(19) United States
(12) Patent Application Publication
(10) Pub. No.: US 2006/0234459 A1
(43) Pub. Date: Oct. 19, 2006

(54) SEMICONDUCTOR DEVICE AND METHOD FOR MANUFACTURING THE SAME

(75) Inventor: Kouichi TANI, Tokyo (JP)

Correspondence Address: GLOBAL IP COUNSELORS, LLP, 1233 20TH STREET, NW, SUITE 700, WASHINGTON, DC, 20036-2680, US

(73) Assignee: OKI ELECTRIC INDUSTRY CO., LTD., Tokyo (JP)

(21) Appl. No.: 11/277,930

(22) Filed: Mar. 29, 2006

(30) Foreign Application Priority Data
Apr. 18, 2005 (JP) 2005/119387

(51) Int. Cl. H01L 21/8222

(52) U.S. Cl. 438/329

(57) ABSTRACT

A method for manufacturing a semiconductor device in which a plurality of wiring layers are formed includes the steps of (a) preparing a semiconductor device on which a plurality of semiconductor elements are formed on one surface thereof, (b) forming a spiral inductor on the semiconductor substrate astride three or more wiring layers, and (c) forming a circuit wiring other than the spiral inductor in the wiring layer. The step of forming the spiral inductor and the step of forming the circuit wiring are performed simultaneously.

### BACKGROUND OF THE INVENTION

### Field of the Invention

The present invention relates to a semiconductor device, and in particular, a semiconductor device having an inductor that functions as a high-frequency passive element and a method for manufacturing the same.

In general, high-frequency radio waves mainly in the microwave band are used in mobile communication devices typified by the cellular phone. In a semiconductor device dealing with this type of microwave bands, it is important to form a passive element (e.g., a capacitor or an inductor) on a semiconductor substrate besides an active element (e.g., a transistor or a diode), and to integrate the passive element with the semiconductor substrate at the same time.

An inductor formed on a semiconductor substrate is a scroll-like inductor, which is generally called “a spiral inductor.” The quality factor (Q-value) is used as an indicator of the inductor's performance. If the Q-value of an inductor is calculated to be high, this means that the inductor has a pure inductance component. In other words, the inductor is an ideal inductor. In order to increase the Q-value, the inductance value must be increased by lengthening the wiring that comprises the inductor. In addition, the resistance value of an inductor must be reduced by forming the wiring to be thick. Because of this, a spiral inductor is generally formed in the top layer of a semiconductor device by using a thick wiring of 1 μm or more in thickness, which is comprised of aluminum (Al).

Japan Patent Publication Application JP-A-09-181264 (especially pages 4 and 5, and FIG. 1) discloses a semiconductor device having a spiral inductor and a method for manufacturing the same. According to the invention disclosed in this publication, an inductor is comprised of a spiral-shaped first conductive film pattern, which is formed on one principal surface of a semiconductor substrate, and an isolated second conductive pattern, which is electrically connected to only the first conductive film pattern through a slit contact and overlapped with the first conductive film pattern. Because of this structure, the wiring resistance of the inductor is reduced and thus the Q-value of the inductor is increased.

In order to miniaturize a semiconductor device, the space occupied by a spiral inductor that is mounted on the semiconductor device must be reduced. However, if a spiral inductor is formed by a thick film wiring that is mostly made from aluminum (Al), problems are caused in processing the wiring materials. For example, the accuracy of processing the wiring materials is reduced by ion scattering in a dry etching step. Because of these problems, there are constraints in the reduction of the width of a wiring and distance between wirings. In other words, in a method for forming a spiral inductor by using thick wiring, there are constraints in reducing the space that is occupied by a spiral inductor. In addition, in terms of manufacturing cost, there is a disadvantage in forming a thick wiring in a single layer. Therefore, a method for thickly forming the structure of a spiral inductor without using a thick film wiring, in other words, a method for reducing resistance, is required. In particular, in terms of rationalization of the manufacturing process, a method for forming a spiral inductor which has a thick film structure at the same time as forming a normal circuit wiring is desired.

According to the invention disclosed in Japan Patent Publication Application JP-A-09-181264, a spiral inductor is comprised of a double-layer structure comprised of a first conductive film pattern, which functions as the main body of the spiral inductor, and an isolated second conductive film pattern, which is electrically connected to the first conductive film pattern. However, a method for forming a spiral inductor astride three or more layers is needed in order to further reduce the resistance of a spiral inductor, that is, to enhance a spiral inductor's performance. There is no disclosure regarding the formation of a spiral inductor astride three or more layers in Japan Patent Publication Application JP-A-09-181264. In addition, in order to rationalize the manufacturing process, it is desirable to simultaneously form a normal circuit wiring and a spiral inductor. However, there is no disclosure regarding the relationship between forming a normal circuit wiring and forming a spiral inductor in Japan Patent Publication Application JP-A-09-181264.

### SUMMARY OF THE INVENTION

It is therefore an object of the present invention to resolve the above described problems, and to provide a semiconductor device in which the space occupied by a spiral inductor can be reduced and a spiral inductor with high performance can be rationally formed.

It is also an object of the present invention to provide a method for manufacturing a semiconductor device, in which the space occupied by a spiral inductor can be reduced and a spiral inductor with high performance can be rationally formed.

According to a first aspect of the present invention, a semiconductor device in which a plurality of wiring layers are formed is comprised of (a) a semiconductor substrate on which a plurality of semiconductor elements are formed on one surface thereof, (b) a spiral inductor that is formed on the semiconductor substrate astride three or more wiring layers, and (c) a circuit wiring other than the spiral inductor, the circuit wiring simultaneously formed with the spiral inductor.

According to a second aspect of the present invention, a method for manufacturing a semiconductor device in which a plurality of wiring layers are formed is comprised of (a) preparing a semiconductor device on which a plurality of semiconductor elements are formed on one surface thereof, (b) forming a spiral inductor on the semiconductor substrate astride three or more wiring layers, and (c) forming a circuit wiring other than the spiral inductor in the wiring layer. Here, steps (b) and (c) are performed simultaneously.

In accordance with the present invention, the normal circuit wiring and the spiral inductor are simultaneously formed. Therefore, the constraints on the width of a wiring and the distance between wirings, which are problems caused in the formation of a spiral inductor by using a single-layered thick film wiring, can be alleviated. Thus, the space occupied by the spiral inductor can be reduced. In addition, according to the present invention, the spiral inductor is formed by forming a normal circuit wiring. Therefore, the manufacturing process can be rationalized, and thus manufacturing costs can be reduced.

These and other objects, features, aspects, and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIGS. 1A and 1B are diagrams showing a method for manufacturing a semiconductor device having a spiral inductor in accordance with a first embodiment of the present invention.

FIGS. 2A and 2B are diagrams showing a method for manufacturing a semiconductor device having a spiral inductor in accordance with the first embodiment of the present invention.

FIGS. 3A and 3B are diagrams showing a method for manufacturing a semiconductor device having a spiral inductor in accordance with the first embodiment of the present invention.

FIGS. 4A and 4B are diagrams showing a method for manufacturing a semiconductor device having a spiral inductor, more specifically, the structure of a finished semiconductor device having a spiral inductor in accordance with the first embodiment of the present invention.

FIGS. 5A and 5B are diagrams showing a method for manufacturing a semiconductor device having a spiral inductor in accordance with a second embodiment of the present invention.

FIGS. 6A and 6B are diagrams showing a method for manufacturing a semiconductor device having a spiral inductor in accordance with the second embodiment of the present invention.

FIGS. 7A and 7B are diagrams showing a method for manufacturing a semiconductor device having a spiral inductor in accordance with the second embodiment of the present invention.

FIGS. 8A and 8B are diagrams showing a method for manufacturing a semiconductor device having a spiral inductor, more specifically, a structure of a finished semiconductor device having a spiral inductor in accordance with the second embodiment of the present invention.

FIGS. 9A and 9B are diagrams showing a method for manufacturing a semiconductor device having a spiral inductor in accordance with a third embodiment of the present invention.

FIGS. 10A and 10B are diagrams showing a method for manufacturing a semiconductor device having a spiral inductor in accordance with the third embodiment of the present invention.

FIGS. 11A and 11B are diagrams showing a method for manufacturing a semiconductor device having a spiral inductor in accordance with the third embodiment of the present invention.

FIGS. 12A and 12B are diagrams showing a method for manufacturing a semiconductor device having a spiral inductor, more specifically, a structure of a finished semiconductor device having a spiral inductor in accordance with the third embodiment of the present invention.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

Referring now to the drawings, preferred embodiments of the present invention will be described in detail.

### First Embodiment

Structure of Semiconductor Device

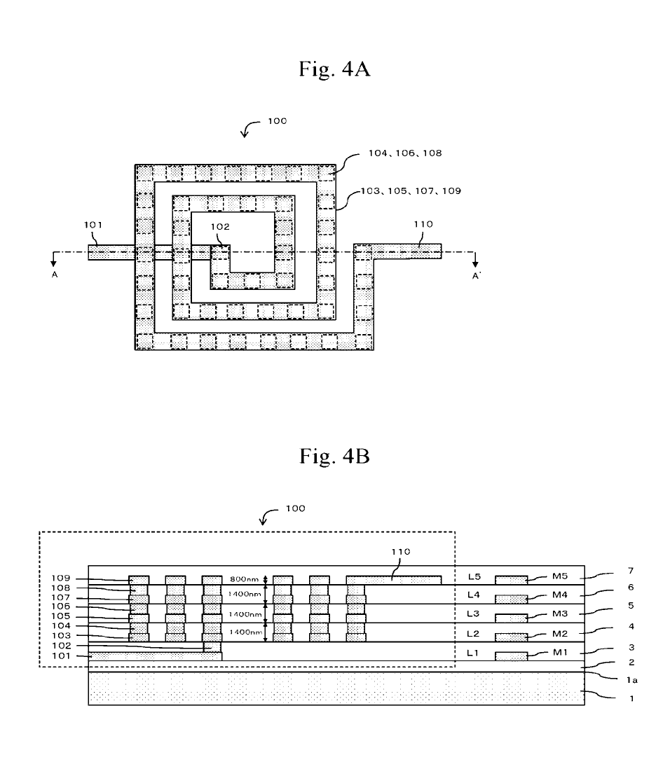

FIGS. 4A and 4B are diagrams showing the structure of a semiconductor device that has a spiral inductor 100 in accordance with the first embodiment of the present invention. More specifically, FIG. 4A is a top plan view of the semiconductor device, and FIG. 4B is a cross-section diagram showing a semiconductor device along line A-A′ shown in FIG. 4A. However, FIG. 4A shows only the structure of a spiral inductor 100 as a matter of convenience. In addition, in the first embodiment of the present invention, a semiconductor device whose wiring layer is comprised of five layers is described as an example. However, application of the present invention is not limited to this type of semiconductor device. It is possible to apply the present invention to a semiconductor device whose wiring layer is comprised of three or more layers.

In FIG. 4B, a semiconductor substrate 1 is a silicon-on-insulator (SOI) substrate or a bulk silicon substrate, for instance. In addition, a plurality of semiconductor elements (not shown in the figure) are formed on a element formation surface 1a of the semiconductor substrate 1. Furthermore, a first wiring layer L1, a second wiring layer L2, a third wiring layer L3, a fourth wiring layer L4, and a fifth wiring layer L5 are sequentially formed above the semiconductor substrate 1 through an insulation film 2.

The first wiring layer L1 is comprised of a lead wiring 101 and a contact 102, both of which form a portion of the spiral inductor 100, a first wiring M1 which is a normal circuit wiring, and an interlayer insulation film 3. The lead wiring 101 connects the spiral inductor 100 with other elements. In the first embodiment of the present invention, the lead wiring 101 and the first wiring M1 are formed in the same wiring formation step. In addition, the first wiring M1 is used for the purpose of forming an electrical circuit by electrically connecting the plurality of semiconductor elements formed on the semiconductor substrate 1. Normally, the first wiring M1 is extensively formed in the first wiring layer L1. However, only a portion of the first wiring M1 is shown in FIG. 4B.

In addition, the second wiring layer L2 is comprised of a first conductive pattern 103 and a plurality of contacts 104, both of which form a portion of the spiral inductor 100, a second wiring M2 which is a normal circuit wiring, and an interlayer insulation film 4. As shown in FIG. 4A, the first conductive pattern 103 is formed in a spiral shape and electrically connected to the lead wiring 101 formed in the first wiring layer L1 through the contact 102. As shown in FIG. 4A, the contacts 104 are illustrated with a dotted line. The contacts 104 are located on the first conductive pattern 103 and formed in an approximately square shape. In the present invention, the first conductive pattern 103 and the second wiring M2 are formed in the same wiring formation step. In addition, the second wiring M2 is used to form an electric circuit by electrically connecting a plurality of semiconductor elements. Normally, the second wiring M2 is extensively formed in the second wiring layer L2. However, only a portion of the second wiring M2 is shown in FIG. 4B.

Furthermore, the third wiring layer L3 is comprised of a second conductive pattern 105 and a plurality of contacts 106, both of which form a portion of the spiral inductor 100, a third wiring M3 which is a normal circuit wiring, and an interlayer insulation film 5. As shown in FIG. 4A, the second conductive pattern 105 is formed in a spiral shape to be overlapped with the first conductive pattern 103 and electrically connected to the first conductive pattern 103 formed in the second wiring layer L2 through the contacts 104. As shown in FIG. 4A, the contacts 106 are illustrated with a dotted line. The contacts 106 are located on the second conductive pattern 105 and formed in an approximately square shape. In addition, the contacts 106 are illustrated to be located immediately above the contacts 104 in FIGS. 4A and 4B. However, the positional relationship between the contacts 106 and the contacts 104 is not necessarily limited to this “immediately below and above” positional relationship. Furthermore, in the first embodiment of the present invention, the second conductive pattern 105 and the third wiring M3 are formed in the same wiring formation process. In addition, the third wiring M3 is used to form an electric circuit by connecting a plurality of semiconductor elements. Normally, the third wiring M3 is extensively formed in the third wiring layer L3. However, only a portion of the third wiring M3 is shown in FIG. 4B.

In addition, the fourth wiring layer L4 is comprised of a third conductive pattern 107 and a plurality of contacts 108, both of which form a portion of the spiral inductor 100, a fourth wiring M4 which is a normal circuit wiring, and an interlayer insulation film 6. As shown in FIG. 4A, the third conductive pattern 107 is formed in a spiral shape to be overlapped with the first conductive pattern 103 and the second conductive pattern 105, and electrically connected to the second conductive pattern 105 formed in the third wiring layer L3 through the contacts 106. As shown in FIG. 4A, the contacts 108 are illustrated with a dotted line. The contacts 108 are located on the third conductive pattern 107 and formed in an approximately square shape. In addition, the contacts 108 are illustrated to be located immediately above the contacts 106 and the contacts 104 in FIGS. 4A and 4B. However, the positional relationship among the contacts 108, the contacts 106, and the contacts 104 is not necessarily limited to this “immediately below and above” relationship. Furthermore, in the first embodiment of the present invention, the third conductive pattern 107 and the fourth wiring M4 are formed in the same wiring formation process. In addition, the fourth wiring M4 is used to form an electric circuit by electrically connecting a plurality of semiconductor elements. Normally the fourth wiring M4 is extensively formed in the fourth wiring layer L4. However, only a portion of the fourth wiring layer L4 is shown in FIG. 4B.

The fifth wiring layer L5 is comprised of a fourth conductive pattern 109 and a lead wiring 110, both of which form a portion of the spiral inductor 100, a fifth wiring M5 which is a normal circuit wiring, and an interlayer insulation film 7. As shown in FIG. 4A, the fourth conductive pattern 109 is formed in a spiral shape to be overlapped with the first conductive pattern 103, the second conductive pattern 105, and the third conductive pattern 107, and electrically connected to the third conductive pattern 107 formed in the fourth wiring layer L4 through the contacts 108. The lead wiring 110 connects the spiral inductor 100 with other elements and it is formed to be connected to an edge of the fourth conductive pattern 109. In the first embodiment of the present invention, the fourth conductive pattern 109, the lead wiring 110, and the fifth wiring M5 are formed in the same wiring formation step. In addition, the fifth wiring M5 is used to form an electric circuit by electrically connecting a plurality of semiconductor elements. Normally the fifth wiring M5 is extensively formed in the fifth wiring layer L5. However, only a portion of the fifth wiring M5 is shown in FIG. 4B.

As described above, it is possible to thickly form the structure of the spiral inductor 100 without using a thick film wiring, by laminating a plurality of spiral conductive patterns over each other (i.e., the first conductive pattern 103, the second conductive pattern 105, the third conductive pattern 107, and the fourth conductive pattern 109) and by forming the spiral inductor 100 by connecting these conductive patterns to each other through the approximately square shaped contacts (i.e., the contacts 104, the contacts 106, and the contacts 108). Because of this, resistance of the spiral inductor 100 can be reduced and thus the Q-value can be increased.

Manufacturing Process

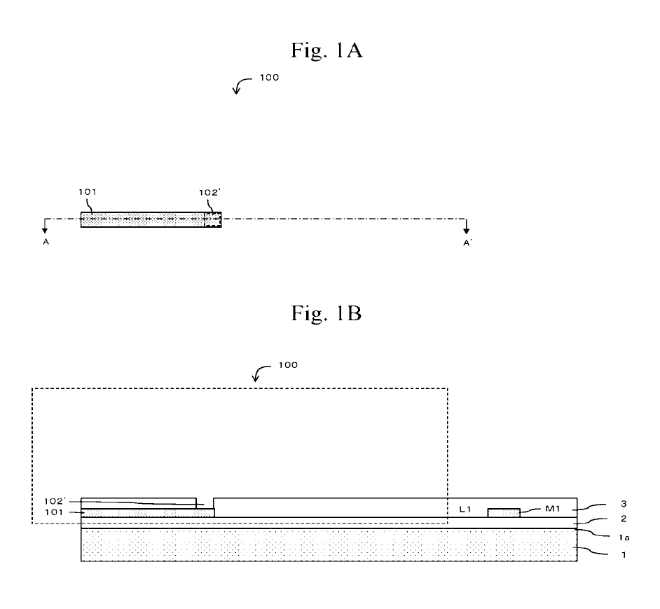

FIGS. 1A, 1B, 2A, 2B, 3A, 3B, 4A, and 4B are diagrams showing a manufacturing process of a semiconductor device having a spiral inductor in accordance with the first embodiment of the present invention. More specifically, FIGS. 1A, 2A, 3A, and 4A are top plan views of the semiconductor device, and FIGS. 1B, 2B, 3B, and 4B are cross-section diagrams of a semiconductor device along line A-A′ in accordance with FIGS. 1A, 2A, 3A, and 4A, respectively. In addition, FIGS. 1A, 2A, 3A, and 4A show only the structure of the spiral inductor 100 as a matter of convenience.

First, as shown in FIG. 1B, an insulation film 2 is formed on a semiconductor substrate 1. The semiconductor substrate 1 is a silicon-on-insulator (SOI) substrate or a bulk silicon substrate, for instance. A plurality of semiconductor elements (not shown in the figure) are formed on an element formation surface 1a of the semiconductor substrate 1. For example, the insulation film 2 is a silicon dioxide film and formed with the normal chemical vapor deposition (CVD) method. Then, a conductive film (e.g., Al alloy) of 800 nm in thickness is deposited on the insulation film 2 with the sputtering method, and a lead wiring 101 that comprises a portion of the spiral inductor 100 and a first wiring M1 that is a normal circuit wiring are formed by patterning the conductive film with photolithoetching. Here, Cu or Cu alloy can be used instead of Al alloy as the wiring material. Next, an insulation film (e.g., a silicon dioxide film) of 2000 nm in thickness is deposited on the first wiring M1, the lead wiring 101, and the insulation film 2 with the CVD method, and the insulation film is planarized with the chemical mechanical polishing (CMP) method. Thus, an interlayer insulation film 3 is formed. For example, thickness of the interlayer insulation film 3 is set to 1400 nm, and thickness of the portions of the interlayer insulation film 3 formed on the lead wiring 101 and the first wiring M1 is set to 600 nm. Then, a contact hole 102′ that exposes a portion of the surface of the lead wiring 101 is formed with photolithoetching. Thus a first wiring layer L1 is formed. In this phase, no conductive materials (e.g., Al alloy) are implanted into the interior of the contact hole 102′.

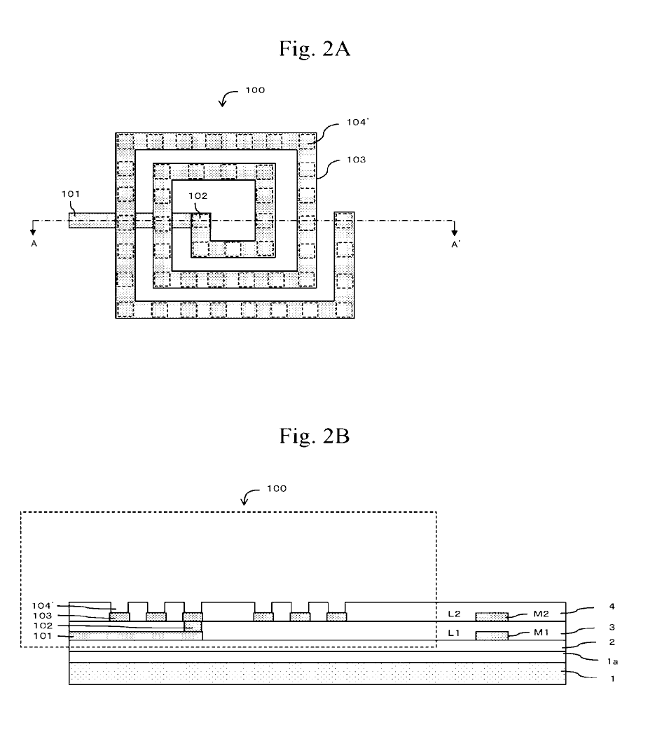

Next, as shown in FIG. 2B, a conductive film (e.g., Al alloy) of 800 nm in thickness is deposited on the interlayer insulation film 3 and the interior of the contact hole 102′ with the sputtering method. Then, a first conductive pattern 103 which comprises a portion of the spiral inductor 100 and a second wiring M2 which is a normal circuit wiring are formed by patterning the conductive film with the photolithoetching. Here, Al alloy is implanted into the interior of the contact hole 102′ and thus a contact 102 is formed. In addition, Cu or Cu Alloy can be used as the wiring material instead of Al alloy. Next, an insulation film (e.g., a silicon dioxide film) of 2000 nm in thickness is deposited on the second wiring M2, the first conductive pattern 103, and the interlayer insulation film 3 with the CVD method. Then, the insulation film is planarized with the CMP method, and thus an interlayer insulation film 4 is formed. The thickness of the interlayer insulation film 4 is set to 1400 nm, for instance. In addition, the thickness of the portions of the interlayer insulation film 4 formed on the first conductive pattern 103 and the second wiring M2 is set to 600 nm. Next, contact holes 104′ that expose portions of the surface of the first conductive pattern 103 are formed with photolithoetching. As shown in FIG. 2A, a plurality of contact holes 104′ are illustrated with a dotted line and formed on the spiral shaped first conductive pattern 103 in an approximately square shape. Thus a second wiring layer L2 is formed. In addition, in this phase, no conductive materials (e.g., Al alloy) are implanted into the interior of the contact holes 104′.

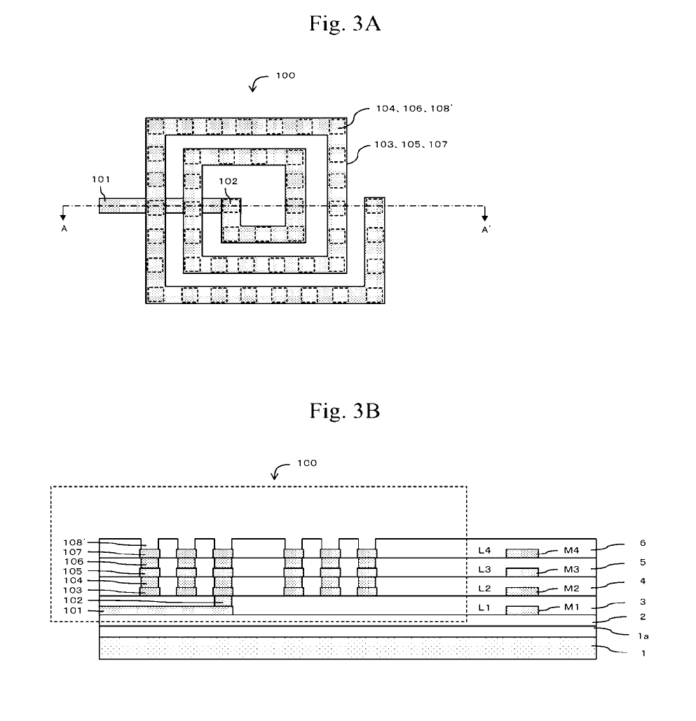

Next, as shown in FIG. 3B, a third wiring layer L3 and a fourth wiring layer L4 are formed by repeating the step of forming the second wiring layer L2, which is explained in reference to FIG. 2B. Here, a second conductive pattern 105 which is formed in the third wiring layer L3 and a third conductive pattern 107 which is formed in the fourth wiring layer L4 form a portion of the spiral inductor 100, and they are formed to planarly overlap with the first conductive pattern 103 formed in the second wiring layer L2. In addition, the first conductive pattern 103 formed in the second wiring layer L2 and the second conductive pattern 105 which is formed in the third wiring layer L3 are connected through a plurality of approximately square shaped contacts 104. On the other hand, the second conductive pattern 105 which is formed in the third wiring layer L3, and the third conductive pattern 107 which is formed in the fourth wiring layer L4, are connected through a plurality of approximately square shaped contacts 106. Furthermore, in this phase, no conductive materials (e.g., Al alloy) are implanted into the interior of contact holes 108′, which are formed in an interlayer insulation film 6 and located on the third conductive pattern 107 formed in the fourth wiring layer L4.

Next, as shown in FIG. 4B, a conductive film (e.g., Al alloy) of 800 nm in thickness is deposited on the interlayer insulation film 6 and into the interior of the contact holes 108′ with the sputtering method. A fourth conductive pattern 109 and a lead wiring 110, both of which form a portion of the spiral inductor 100, and a fifth wiring M5 which is a normal circuit wiring are formed by patterning the conductive film with photolithoetching. Here, Al alloy is implanted into the interior of the contact holes 108′ and thus contact holes 108 are formed. In addition, Cu or Cu alloy can be used as the wiring material instead of Al alloy. Next, an insulation film (e.g., a silicon dioxide film) of 2000 nm in thickness is deposited on the fifth wiring M5, the fourth conductive pattern 109, the lead wiring 110, and the interlayer insulating film 6 with the CVD method. Then the insulation film is planarized with the CMP method and thus an interlayer insulation film 7 is formed. The thickness of the interlayer insulation film 7 is set to 1400 nm, for instance. The thickness of the portions of the interlayer insulation film 7 formed on the fourth conductive pattern 109, the lead wiring 110, and the fifth wiring M5 is set to 600 nm. Thus, a semiconductor device having the spiral inductor 100 is formed.

Here, as an example, the thickness “d” of the spiral inductor 100 can be calculated as follows. As shown in FIG. 4B, the thickness d is calculated by adding the thicknesses of the second wiring layer L2, the third wiring layer L3, the fourth wiring layer L4, and the fifth wiring layer L5 (i.e., d=1400 nm×3+800 nm=5000 nm). Therefore, it is easy to form a spiral inductor of 5 or more μm in thickness.

According to the method for manufacturing a semiconductor device in accordance with the first embodiment of the present invention, the normal circuit wirings (i.e., the first to fifth wirings M1 to M5) and the conductive patterns (i.e., the first to fourth conductive patterns 103, 105, 107, and 109) are simultaneously formed, and the spiral inductor is formed by connecting the conductive patterns through the approximately square shaped contacts (i.e., contacts 102, 104, 106, and 108), respectively. Thus, constraints in the width of the wiring and the distance between wirings, which are problems caused during the formation of a spiral inductor by using a single layered thick wiring, are alleviated. Because of this, it is possible to reduce the space occupied by the spiral inductor, and thus it is possible to miniaturize a semiconductor device. In addition, the spiral inductor is formed by using a step of forming a normal circuit wiring. Therefore, it is possible to rationalize the manufacturing process and thus it is possible to reduce manufacturing costs. In addition, it becomes possible to easily form a spiral inductor in which a thick film structure is formed astride three layers. Because of this, it is possible to further reduce resistance of the spiral inductor, and thus it is possible to enhance the spiral inductor's performance. Furthermore, the conductive patterns are connected through a plurality of contacts. Therefore, it is possible to reduce resistance of the spiral inductor, and thus it is possible to enhance the spiral inductor's performance.

In addition, according to the first embodiment of the present invention, the contacts 104, the contacts 106, and the contacts 108 are formed with respect to each of the conductive patterns in each layer (i.e., the first to fourth conductive patterns 103, 105, 107, and 109) in order to connect adjacent conductive patterns. In this case, it is possible to inhibit the aspect ratio of the contact holes 104′, 106′, and 108′. Because of this, it is easy to implant conductive materials into the contact holes 104′, 106′, and 108′.

In addition, according to the first embodiment of the present invention, a conductive pattern and contacts are simultaneously formed in each layer. Therefore, it is possible to simplify the manufacturing process. More specifically, when the combinations of the first conductive pattern 103 and the contact 102, the second conductive pattern 105 and the contacts 104, the third conductive pattern 107 and the contacts 106, and the fourth conductive pattern 109 and the contacts 108 are simultaneously formed, respectively, it is possible to simplify the manufacturing processes of a conductive pattern and contacts in each layer.

In addition, according to the first embodiment of the present invention, as shown in FIGS. 2A, 2B, 3A, 3B, 4A, and 4B, the contact hole 102′ is formed in an end portion of the lead wiring 101. Because of this, it is possible to form the lead wiring 101 in the minimum length. Furthermore, a plurality of contact holes 102′ may be formed in an end portion of the lead wiring 101. On the other hand, one of the contact holes 108′ is formed in an end portion of the lead wiring 110. Because of this, it is possible to form the lead wiring 110 in the minimum length. In addition, a plurality of contact holes 108′ may be formed in an end of the lead wiring 110.

Furthermore, the lead wirings 101 and 110, the first to fourth conductive patterns 103, 105, 107, and 109, and the contacts 102, 104, 106, and 108 may be formed with an aluminum alloy (i.e., an alloy mainly comprised of aluminum). In this case, it is possible to form the spiral inductor by using a heretofore known method for forming a wiring layer.

### Second Embodiment

Structure of Semiconductor Device

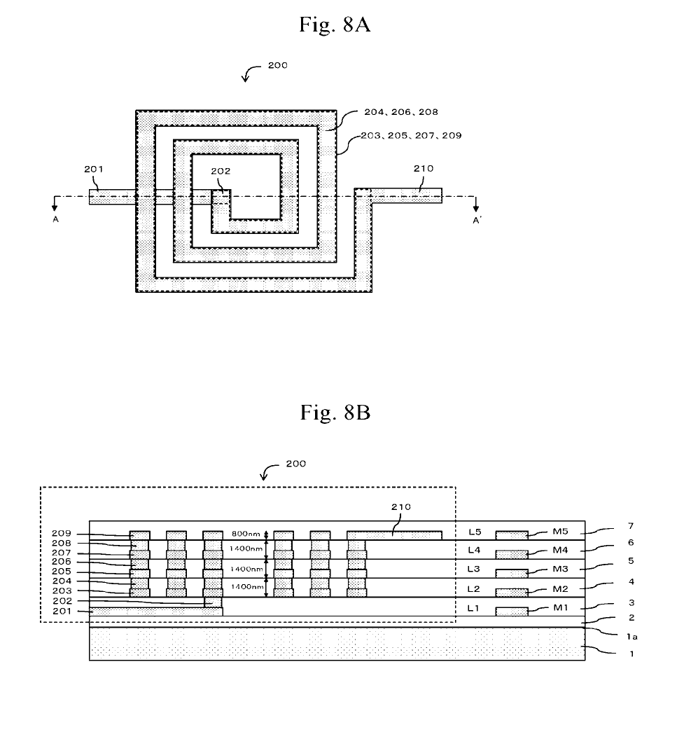

FIGS. 8A and 8B are diagrams showing the structure of a semiconductor device that has a spiral inductor 200 in accordance with the second embodiment of the present invention. More specifically, FIG. 8A is a top plan view of the semiconductor device, and FIG. 8B is a cross-section diagram showing a semiconductor device taken along line A-A′ shown in FIG. 8A. However, FIG. 8A shows only the structure of a spiral inductor 200 as a matter of convenience. In addition, in the second embodiment of the present invention, a semiconductor device whose wiring layer is comprised of five layers is explained as an example. However, application of the present invention is not limited to this type of semiconductor device. It is possible to apply the present invention to a semiconductor device whose wiring layer is comprised of three or more layers.

In FIG. 8B, a semiconductor substrate 1 is a silicon-on-insulator (SOI) substrate or a bulk silicon substrate, for instance. In addition, a plurality of semiconductor elements (not shown in the figure) are formed on a element formation surface 1a of the semiconductor substrate 1. Furthermore, a first wiring layer L1, a second wiring layer L2, a third wiring layer L3, a fourth wiring layer L4, and a fifth wiring layer L5 are sequentially formed above the semiconductor substrate 1 through an insulation film 2.

The first wiring layer L1 is comprised of a lead wiring 201 and a contact 202, both of which form a portion of the spiral inductor 200, a first wiring M1 which is a normal circuit wiring, and an interlayer insulation film 3. The lead wiring 201 connects the spiral inductor 200 with other elements. In the second embodiment of the present invention, the lead wiring 201 and the first wiring M1 are formed in the same wiring formation step. In addition, the first wiring M1 is used for the purpose of forming an electrical circuit by electrically connecting the plurality of semiconductor elements formed on the semiconductor substrate 1. Normally, the first wiring M1 is extensively formed in the first wiring layer L1. However, only a portion of the first wiring M1 is shown in FIG. 8B.

In addition, the second wiring layer L2 is comprised of a first conductive pattern 203 and a contact 204, both of which form a portion of the spiral inductor 200, a second wiring M2 which is a normal circuit wiring, and an interlayer insulation film 4. As shown in FIG. 8A, the first conductive pattern 203 is formed in a spiral shape and electrically connected to the lead wiring 201 formed in the first wiring layer L1 through the contact 202. As shown in FIG. 8A, the contact 204 is illustrated with a dotted line. The contact 204 is located along the first conductive pattern 203 and formed in a slit shape or a narrow slit shape. More specifically, the contact 204 is formed to be approximately aligned with the first conductive pattern 203 when seen in the top view. In the present invention, the first conductive pattern 203 and the second wiring M2 are formed in the same wiring formation step. In addition, the second wiring M2 is used to form an electric circuit by electrically connecting a plurality of semiconductor elements. Normally, the second wiring M2 is extensively formed in the second wiring layer L2. However, only a portion of the second wiring M2 is shown in FIG. 8B.

Furthermore, the third wiring layer L3 is comprised of a second conductive pattern 205 and the contact 206, both of which form a portion of the spiral inductor 200, a third wiring M3 which is a normal circuit wiring, and an interlayer insulation film 5. As shown in FIG. 8A, the second conductive pattern 205 is formed in a spiral shape to be overlapped with the first conductive pattern 203 and electrically connected to the first conductive pattern 203 formed in the second wiring layer L2 through the contact 204. As shown in FIG. 8A, the contact 206 is illustrated with a dotted line. The contact 206 is located along the second conductive pattern 205 and formed in a slit shape or a narrow slit shape. More specifically, the contact 206 is formed to be approximately aligned with the second conductive pattern 205 when seen in the top view. In addition, in the second embodiment of the present invention, the second conductive pattern 205 and the third wiring M3 are formed in the same wiring formation process. In addition, the third wiring M3 is used to form an electric circuit by connecting a plurality of semiconductor elements. Normally, the third wiring M3 is extensively formed in the third wiring layer L3. However, only a portion of the third wiring M3 is shown in FIG. 8B.

In addition, the fourth wiring layer L4 is comprised of a third conductive pattern 207 and a contact 208, both of which form a portion of the spiral inductor 200, a fourth wiring M4 which is a normal circuit wiring, and an interlayer insulation film 6. As shown in FIG. 8A, the third conductive pattern 207 is formed in a spiral shape to be overlapped with the first conductive pattern 203 and the second conductive pattern 205, and electrically connected to the second conductive pattern 205 formed in the third wiring layer L3 through the contact 206. In addition, as shown in FIG. 8A, the contact 208 is illustrated with a dotted line. The contact 208 is located on the third conductive pattern 207 and formed along the third conductive pattern 207 in a slit shape or a narrow slit shape. More specifically, the contact 208 is formed to be approximately aligned with the third conductive pattern 207 when seen in the top view. In the second embodiment of the present invention, the third conductive pattern 207 and the fourth wiring M4 are formed in the same wiring formation step. In addition, the fourth wiring M4 forms an electric circuit by electrically connecting a plurality of semiconductor elements. Normally, the fourth wiring M4 is extensively formed in the fourth wiring layer L4. However, only a portion of the fourth wiring layer L4 is shown in FIG. 8B.

The wiring layer L5 is comprised of a fourth conductive pattern 209 and a lead wiring 210, both of which form a portion of the spiral inductor 200, a fifth wiring M5 which is a normal circuit wiring, and an interlayer insulation film 7.

As shown in FIG. 8A, the fourth conductive pattern 209 is formed in a spiral shape to be overlapped with the first conductive pattern 203, the second conductive pattern 205, and the third conductive pattern 207, and electrically connected to the third conductive pattern 207 formed in the fourth wiring layer L4 through the contact 208. The lead wiring 210 connects the spiral inductor 200 with other elements, and it is formed to be connected to an end portion of the fourth conductive pattern 209. In addition, in the second embodiment of the present invention, the fourth conductive pattern 209, the lead wiring 210, and the fifth wiring M5 are formed in the same wiring formation process. In addition, the fifth wiring M5 is used to form an electric circuit by electrically connecting a plurality of semiconductor elements. Normally the fifth wiring M5 is extensively formed in the fifth wiring layer L5. However, only a portion of the fifth wiring layer L5 is shown in FIG. 8B.

As described above, it is possible to thickly form the structure of the spiral inductor 200 without using a thick film wiring, by planarly laminating a plurality of spiral conductive patterns (i.e., the first conductive pattern 203, the second conductive pattern 205, the third conductive pattern 207, and the fourth conductive pattern 209) over each other and by comprising the spiral inductor 200 by connecting these conductive patterns to each other through the slit shaped contacts or the narrow slit shaped contacts (i.e., the contacts 204, the contacts 206, and the contacts 208). In addition, according to the second embodiment of the present invention, contacts are formed along the conductive patterns in a slit shape or a narrow slit shape. More specifically, the contacts are formed to be approximately aligned with the conductive patterns when seen in the top view. Therefore, resistance of the spiral inductor 200 can be further reduced and thus the Q-value can be further increased, compared to the above described first embodiment of the present invention in which a plurality of contacts are formed in an approximately square shape.

Manufacturing Process

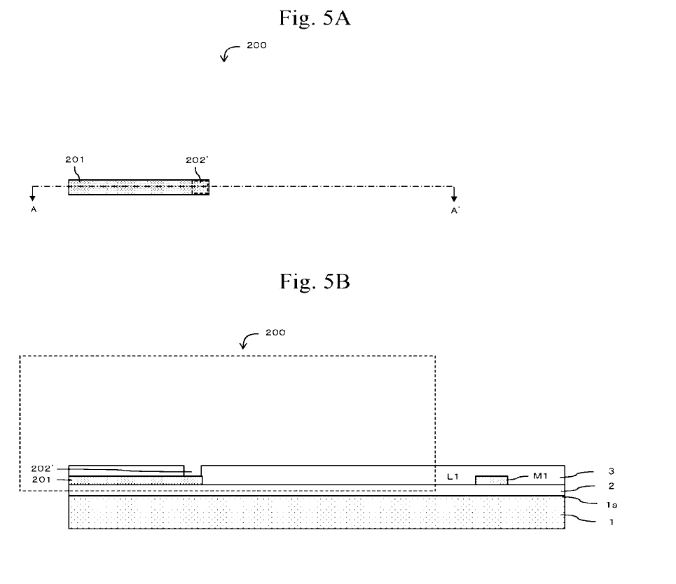

FIGS. 5A, 5B, 6A, 6C, 7A, 7B, 8A, and 8B are diagrams showing a manufacturing process of a semiconductor device having a spiral inductor 200 in accordance with the second embodiment of the present invention. More specifically, FIGS. 5A, 6A, 7A, and 8A are top plan views of the semiconductor device, and FIGS. 5B, 6B, 7B, and 8B are cross-section diagrams of a semiconductor device taken along line A-A′ in accordance with FIGS. 5A, 6A, 7A, and 8A, respectively. In addition, FIGS. 5A, 6A, 7A, and 8A show only the structure of the spiral inductor 200 as a matter of convenience.

First, as shown in FIG. 5B, an insulation film 2 is formed on a semiconductor substrate 1. The semiconductor substrate 1 is a silicon-on-insulator (SOI) substrate or a bulk silicon substrate, for instance. A plurality of semiconductor elements (not shown in the figure) are formed on an element formation surface 1a of the semiconductor substrate 1. For example, the insulation film 2 is a silicon dioxide film and formed with the normal chemical vapor deposition (CVD) method. Then, a conductive film (e.g., Al alloy) of 800 nm in thickness is deposited on the insulation film 2 with the sputtering method, and a lead wiring 201 that comprises a portion of the spiral inductor 200 and a first wiring M1 that is a normal circuit wiring are formed by patterning the conductive film with photolithoetching. Here, Cu or Cu alloy can be used instead of Al alloy as the wiring material. Next, an insulation film (e.g., a silicon dioxide film) of 2000 nm in thickness is deposited on the first wiring M1, the lead wiring 201, and the insulation film 2 with the CVD method, and the insulation film is planarized with the chemical mechanical polishing (CMP) method. Thus an interlayer insulation film 3 is formed. For example, thickness of the interlayer insulation film 3 is set to 1400 nm, and thickness of the portions of the interlayer insulation film 3 formed on the lead wiring 201 and the first wiring M1 is set to 600 nm. Then, a contact hole 202′ that exposes a portion of the surface of the lead wiring 201 is formed with photolithoetching. Thus a first wiring layer L1 is formed. In this phase, no conductive materials (e.g., Al alloy) are implanted into the interior of the contact hole 202′.

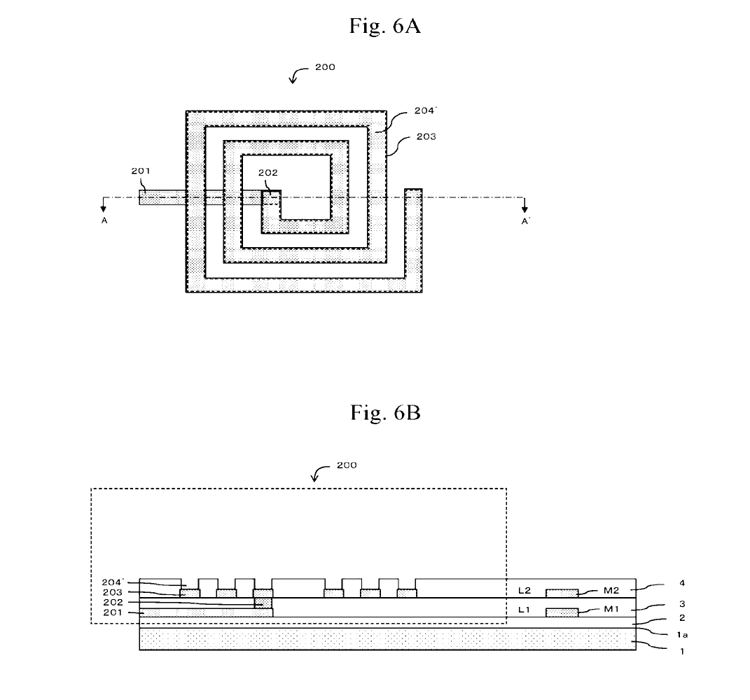

Next, as shown in FIG. 6B, a conductive film (e.g., Al alloy) of 800 nm in thickness is deposited on the interlayer insulation film 3 and the interior of the contact hole 202′ with the sputtering method. Then, a first conductive pattern 203 which comprises a portion of the spiral inductor 200 and a second wiring M2 which is a normal circuit wiring are formed by patterning the conductive film with the photolithoetching. Here, Al alloy is implanted into the interior of the contact hole 202′ and thus a contact 202 is formed. In addition, Cu or Cu alloy can be used as the wiring material instead of Al alloy. Next, an insulation film (e.g., a silicon dioxide film) of 2000 nm in thickness is deposited on the second wiring M2, the first conductive pattern 203, and the interlayer insulation film 3 with the CVD method. Then, the insulation film is planarized with the CMP method, and thus an interlayer insulation film 4 is formed. Thickness of the interlayer insulation film 4 is set to 1400 nm, for instance. In addition, thickness of the portions of the interlayer insulation film 4 formed on the first conductive pattern 203 and the second wiring M2 is set to 600 nm. Next, contact hole 204′ that expose portions of the surface of the first conductive pattern 203 is formed with photolithoetching. As shown in FIG. 6A, the contact hole 204′ is illustrated with a dotted line and formed along the spiral shaped first conductive pattern 203 in a slit shape or a narrow slit shape. More specifically, the contact hole 204′ is formed to be approximately aligned with the first conductive pattern 203 when seen in the top view. Thus a second wiring layer L2 is formed. In addition, in this phase, no conductive materials (e.g., Al alloy) are implanted into the interior of the contact hole 204′.

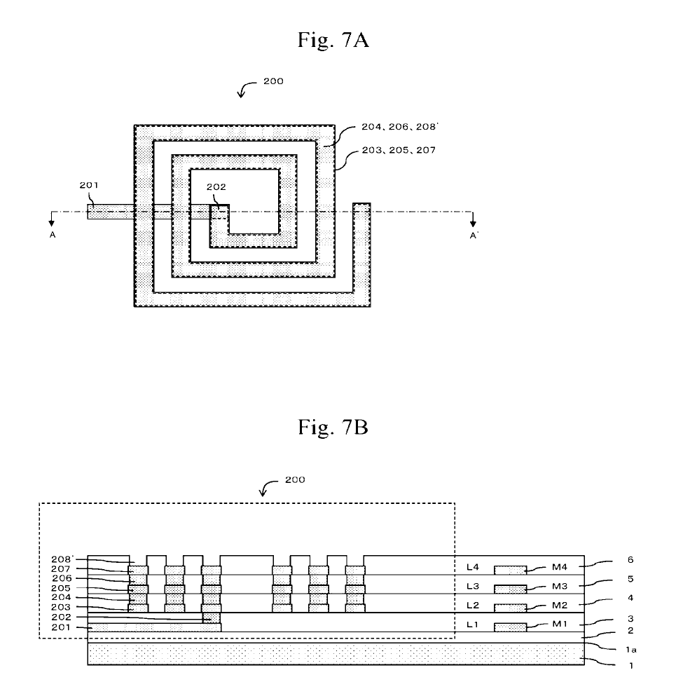

Next, as shown in FIG. 7B, a third wiring layer L3 and a fourth wiring layer L4 are formed by repeating the step of forming the second wiring layer L2, which is explained in reference to FIG. 6B. Here, a second conductive pattern 205 which is formed in the third wiring layer L3 and a second conductive pattern 207 which is formed in the fourth wiring layer L4 form a portion of the spiral inductor 200, and they are formed to be planarly overlapped with the first conductive pattern 203 formed in the second wiring layer L2. In addition, the first conductive pattern 203 formed in the second wiring layer L2 and the second conductive pattern 205 which is formed in the third wiring layer L3 are connected through a slit contact (or a narrow slit contact) 204. On the other hand, the second conductive pattern 205 which is formed in the third wiring layer L3 and the third conductive pattern 207 which is formed in the fourth wiring layer L4 are connected through a slit contact (or a narrow slit contact) 206. In addition, in this phase, conductive materials (e.g., Al alloy) have not been implanted into the interior of a contact hole 208′, which is formed in an interlayer insulation film 6 and located on the third conductive pattern 207 formed in the fourth wiring layer L4. Next, as shown in FIG. 8B, a conductive film (e.g., Al alloy) of 800 nm in thickness is deposited on the interlayer insulation film 6 and into the interior of the contact hole 208′ with the sputtering method. A fourth conductive pattern 209 and a lead wiring 210, both of which form a portion of the spiral inductor 200, and a fifth wiring M5 which is a normal circuit wiring are formed by patterning the conductive film with photolithoetching. Here, Al alloy is implanted into the interior of the contact hole 208′ and thus a contact 208 is formed. In addition, Cu or Cu alloy can be used as the wiring material instead of Al alloy. Next, an insulation film (e.g., a silicon dioxide film) of 2000 nm in thickness is deposited on the fifth wiring M5, the fourth conductive pattern 209, the lead wiring 210, and the interlayer insulating film 6 with the CVD method. Then the insulation film is planarized with the CMP method and thus an interlayer insulation film 7 is formed. The thickness of the interlayer insulation film 7 is set to 1400 nm, for instance. The thickness of the portions of the interlayer insulation film 7 formed on the fourth conductive pattern 209, the lead wiring 210, and the fifth wiring M5 is set to 600 nm. Thus a semiconductor device having the spiral inductor 200 is formed. Here, as an example, the thickness “d” of the spiral inductor 200 can be calculated as follows. As shown in FIG. 8B, the thickness d is calculated by adding the thicknesses of the second wiring layer L2, the third wiring layer L3, the fourth wiring layer L4, and the fifth wiring layer L5 (i.e., d=1400 nm×3+800 nm=5000 nm). Therefore, it is easy to form a spiral inductor of 5 or more μm in thickness.

According to the method for manufacturing a semiconductor device in accordance with the second embodiment of the present invention, the normal circuit wirings (i.e., the first to fifth wirings M1 to M5) and the conductive patterns (i.e., the first to fourth conductive patterns 203, 205, 207, and 209) are simultaneously formed, and the spiral inductor is formed by connecting the conductive patterns through the slit shaped or narrow slit shaped contacts (i.e., contacts 202, 204, 206, and 208), respectively. Thus, constraints in the width of the wiring and the distance between wirings, which are caused during the formation of the spiral inductor by using a single layered thick wiring, are alleviated. Because of this, it is possible to reduce the space occupied by the spiral inductor, and thus it is possible to miniaturize a semiconductor device. In addition, the spiral inductor is formed by using a step of forming a normal circuit wiring. Therefore, it is possible to rationalize the manufacturing process, and thus it is possible to reduce manufacturing costs. In addition, it becomes possible to easily form a spiral inductor in which a thick film structure is formed astride three layers. Because of this, it is possible to further reduce the resistance of the spiral inductor, and thus it is possible to enhance the spiral inductor's performance. Furthermore, contacts are formed along the conductive patterns in a slit shape or a narrow slit shape. More specifically, contacts are formed to be approximately aligned with the conductive patterns when seen in the top view. Therefore, it is possible to further reduce the resistance of the spiral inductor, and thus it is possible to enhance the spiral inductor's performance, compared the above described first embodiment in which a plurality of contacts are formed in an approximately square shape.

In addition, according to the second embodiment of the present invention, the contacts 204, 206, and 208 are formed with respect to each of the conductive patterns in each layer (i.e., the first to fourth conductive patterns 203, 205, 207, and 209) in order to connect adjacent conductive patterns. In this case, it is possible to inhibit the aspect ratio of the contact holes 202′, 204′, 206′ and 208′. Because of this, it is easy to implant conductive materials into the contact holes 202′, 204′, 206′ and 208′.

Furthermore, according to the second embodiment of the present invention, a conductive pattern and a contact are simultaneously formed in each layer. Therefore, it is possible to simplify the manufacturing process. More specifically, when the combinations of the first conductive pattern 203 and the contact 202, the second conductive pattern 205 and the contact 204, the third conductive pattern 207 and the contact 206, and the fourth conductive pattern 209 and the contact 208 are simultaneously formed, respectively, it is possible to simplify the manufacturing process for the conductive pattern and contact in each layer.

In addition, as shown in FIGS. 5A, 5B, 6A, 6B, 7A, 7B, 8A, and 8B, the contact hole 202′ is formed in an end portion of the lead wiring 201. Because of this, it is possible to form the lead wiring 201 in the minimum length. In addition, a plurality of contact holes 202′ may be formed in an end portion of the lead wiring 201. On the other hand, a portion of the contact hole 208′ is formed in an end portion of the lead wiring 210. Because of this, it is possible to form the lead wiring 210 in the minimum length. In addition, a plurality of contact holes 208′ may be formed in an end of the lead wiring 210.

Furthermore, the lead wirings 201 and 210, the first to fourth conductive patterns 203, 205, 207, 209, and the contacts 202, 204, 206, 208 may be formed with an aluminum alloy (i.e., an alloy mainly comprised of aluminum). In this case, it is possible to form the spiral inductor by using a heretofore known method for forming a wiring layer.

### Third Embodiment

Structure of Semiconductor Device

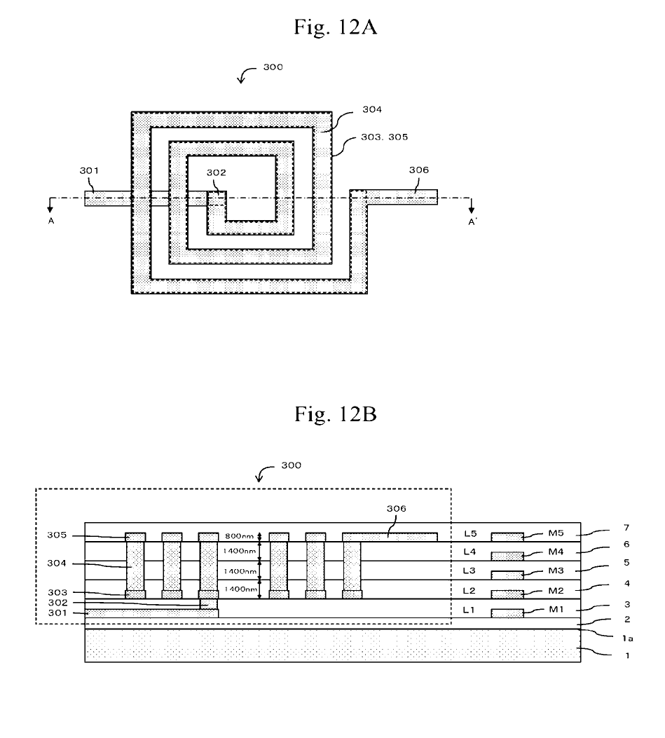

FIGS. 12A and 12B are diagrams showing the structure of a semiconductor device that has a spiral inductor 300 in accordance with the third embodiment of the present invention. More specifically, FIG. 12A is a top plan view of the semiconductor device, and FIG. 12B is a cross-section diagram showing a semiconductor device along line A-A′ shown in FIG. 12A. However, FIG. 12A shows only the structure of a spiral inductor 300 as a matter of convenience. In addition, in the third embodiment of the present invention, a semiconductor device whose wiring layer is comprised of five layers is explained as an example. However, application of the present invention is not limited to this type of semiconductor device. It is possible to apply the present invention to a semiconductor device whose wiring layer is comprised of three or more layers.

In FIG. 12B, a semiconductor substrate 1 is a silicon-on-insulator (SOI) substrate or a bulk silicon substrate, for instance. In addition, a plurality of semiconductor elements (not shown in the figure) are formed on a element formation surface 1a of the semiconductor substrate 1. Furthermore, a first wiring layer L1, a second wiring layer L2, a third wiring layer L3, a fourth wiring layer L4, and a fifth wiring layer L5 are sequentially formed above the semiconductor substrate 1 through an insulation film 2.

The first wiring layer L1 is comprised of a lead wiring 301 and a contact 302, both of which form a portion of the spiral inductor 300, a first wiring M1 which is a normal circuit wiring, and an interlayer insulation film 3. The lead wiring 301 connects the spiral inductor 300 with other elements. In the third embodiment of the present invention, the lead wiring 301 and the first wiring M1 are formed in the same wiring formation step. In addition, the first wiring M1 is used for the purpose of comprising an electrical circuit by electrically connecting the plurality of semiconductor elements formed on the semiconductor substrate 1. Normally, the first wiring M1 is extensively formed in the first wiring layer L1. However, only a portion of the first wiring M1 is shown in FIG. 12B.

In addition, the second wiring layer L2 is comprised of a first conductive pattern 303 and a portion of a contact 304 which is formed astride the second to fourth wiring layers L2 to L4, both of which form a portion of the spiral inductor 300, a second wiring M2 which is a normal circuit wiring, and an interlayer insulation film 4. As shown in FIG. 12A, the first conductive pattern 303 is formed in a spiral shape and electrically connected to the lead wiring 301 formed in the first wiring layer L1 through the contact 302. As shown in FIG. 12A, the contact 304 is illustrated with a dotted line. The contact 304 is located on the first conductive pattern 303 and formed along the first conductive pattern 303 in a slit shape or a narrow slit shape. More specifically, the contact 304 is formed to be approximately aligned with the first conductive pattern 303 when seen in the top view. In the present invention, the first conductive pattern 303 and the second wiring M2 are formed in the same wiring formation step. In addition, the second wiring M2 is used to form an electric circuit by electrically connecting a plurality of semiconductor elements. Normally, the second wiring M2 is extensively formed in the second wiring layer L2. However, only a portion of the second wiring M2 is shown in FIG. 12B.

In addition, the third wiring layer L3 is comprised of a portion of the contact 304 which is formed astride the second to fourth wiring layers L2 to L4 and comprises a portion of the spiral inductor 300, a third wiring M3 which is a normal circuit wiring, and an interlayer insulation film 5. Here, the third wiring M3 is used for the purpose of comprising an electric circuit by electrically connecting the plurality of semiconductor elements. Normally, the third wiring M3 is extensively formed in the third wiring layer L3. However, only a portion of the third wiring M3 is shown in FIG. 12B.

The fourth wiring layer L4 is comprised of a portion of the contact 304 which is formed astride the second to fourth wiring layers L2 to L4 and comprises a portion of the spiral inductor 300, a fourth wiring M4 which is a normal circuit wiring, and an interlayer insulation film 6. Here, the fourth wiring M4 is used for the purpose of comprising an electric circuit by electrically connecting a plurality of semiconductor elements. Normally, the fourth wiring M4 is extensively formed in the fourth wiring layer L4. However, only a portion of the fourth wiring M4 is shown in FIG. 12B.

The fifth wiring layer L5 is comprised of a second conductive pattern 305 and a lead wiring 306, both of which form a portion of the spiral inductor 300, a fifth wiring M5 which is a normal circuit wiring, and an interlayer insulation 7.

As shown in FIG. 12A, the second conductive pattern 305 is formed in a spiral shape to be overlapped with the first conductive pattern 303 and electrically connected to the first conductive pattern 303 formed in the second wiring layer L2 through the contact 304. The lead wiring 306 connects the spiral inductor 300 with other elements, and it is formed to be connected an end portion of the second conductive pattern 305. In addition, in the third embodiment of the present invention, the second conductive pattern 305, the lead wiring 306, and the fifth wiring M5 are formed in the same wiring formation process. In addition, the fifth wiring M5 is used to form an electric circuit by connecting a plurality of semiconductor elements. Normally, the fifth wiring M5 is extensively formed in the fifth wiring layer L5. However, only a portion of the fifth wiring M5 is shown in FIG. 12B.

As described above, it is possible to thickly form the structure of the spiral inductor 300 without using a thick film wiring, by planarly laminating two layers of the conductive patterns over each other (i.e., the first conductive pattern 303 and the second conductive pattern 305) and by comprising the spiral inductor 300 by connecting both conductive patterns through a slit shaped contact or a narrow slit contact (i.e., the contacts 304). In addition, according to the third embodiment of the present invention, as described below, a slit contact (or a narrow slit contact) is formed by using pure aluminum as a material with a selective aluminum chemical vapor deposition method (selective Al CVD method). Therefore, it is possible to further reduce resistance of the spiral inductor 300 and thus it is possible to increase the Q value, compared to the case in which Al alloy is used with a general sputtering method.

Manufacturing Process

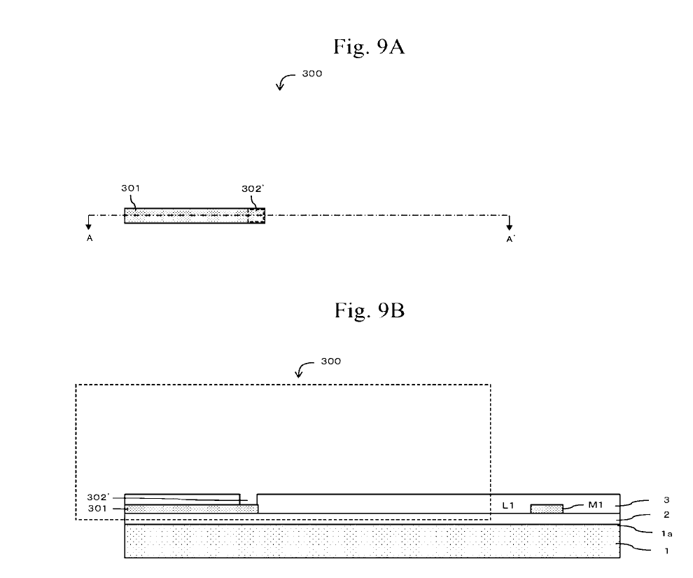

FIGS. 9A, 9B, 10A, 10B, 11A, 11B, 12A, and 12B are diagrams showing a manufacturing process of a semiconductor device having a spiral inductor 300 in accordance with the third embodiment of the present invention. More specifically, FIGS. 9A, 10A, 11A, and 12A are top plan views of the semiconductor device, and FIGS. 9B, 10B, 11B, and 12B are cross-section diagrams of a semiconductor device along line A-A′ in accordance with FIGS. 9A, 10A, 11A, and 12A, respectively. In addition, FIGS. 9A, 10A, 11A, and 12A show only the structure of the spiral inductor 300 as a matter of convenience.

First, as shown in FIG. 9B, an insulation film 2 is formed on a semiconductor substrate 1. The semiconductor substrate 1 is a silicon-on-insulator (SOI) substrate or a bulk silicon substrate, for instance. A plurality of semiconductor elements (not shown in the figure) are formed on an element formation surface 1a of the semiconductor substrate 1. For example, the insulation film 2 is a silicon dioxide film and formed with the normal chemical vapor deposition (CVD) method. Then, a conductive film (e.g., Al alloy) of 800 nm in thickness is deposited on the insulation film 2 with the sputtering method, and a lead wiring 301 that comprises a portion of the spiral inductor 300 and a first wiring M1 that is a normal circuit wiring are formed by patterning the conductive film with photolithoetching. Next, an insulation film (e.g., a silicon dioxide film) of 2000 nm in thickness is deposited on the first wiring M1, the lead wiring 301, and the insulation film 2 with the CVD method, and the insulation film is planarized with the chemical mechanical polishing (CMP) method. Thus, an interlayer insulation film 3 is formed. For example, thickness of the interlayer insulation film 3 is set to 1400 nm, and thickness of the portions of the interlayer insulation film 3 formed on the lead wiring 301 and the first wiring M1 is set to 600 nm. Then, a contact hole 302′ that exposes a portion of the surface of the lead wiring 301 is formed with photolithoetching. Thus a first wiring layer L1 is formed. In this phase, no conductive materials (e.g., Al alloy) are implanted into the interior of the contact hole 302′.

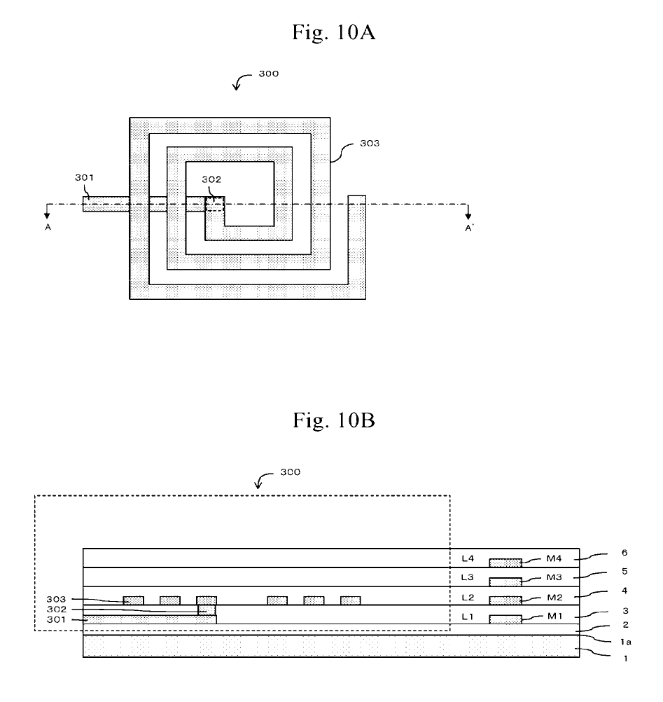

Next, as shown in FIG. 10B, a conductive film (e.g., Al alloy) of 800 nm in thickness is deposited on the interlayer insulation film 3 and the interior of the contact hole 302′ with the sputtering method. Then, a first conductive pattern 303 which comprises a portion of the spiral inductor 300 and a second wiring M2 which is a normal circuit wiring are formed by patterning the conductive film with the photolithoetching. Here, Al alloy is implanted into the interior of the contact hole 302′ and thus a contact 302 is formed. Next, an insulation film (e.g., a silicon dioxide film) of 2000 nm in thickness is deposited on the second wiring M2, the first conductive pattern 303, and the interlayer insulation film 3 with the CVD method. Then, the insulation film is planarized with the CMP method, and thus an interlayer insulation film 4 is formed. Thickness of the interlayer insulation film 4 is set to 1400 nm, for instance. In addition, thickness of the portions of the interlayer insulation film 4 formed on the first conductive pattern 303 and the second wiring M2 is set to 600 nm. Thus a second wiring layer L2 is formed. Next, a third wiring layer L3 that is comprised of an interlayer insulation film 5 and a third wiring M3, and a fourth wiring layer L4 that is comprised of an interlayer insulation film 6 and a fourth wiring M4 are sequentially formed by using the similar way that is used to form the second wiring layer L2. Here, thickness of the interlayer insulation film 5 is set to 1400 nm, and thickness of the portion of the interlayer insulation film 5 formed on the third wiring M3 is set to 600 nm, for instance. In addition, thickness of the interlayer insulation film 6 is set to 1400 nm, and thickness of the portion of the interlayer insulation film 6 formed on the fourth wiring M4 is set to 600 nm, for instance.

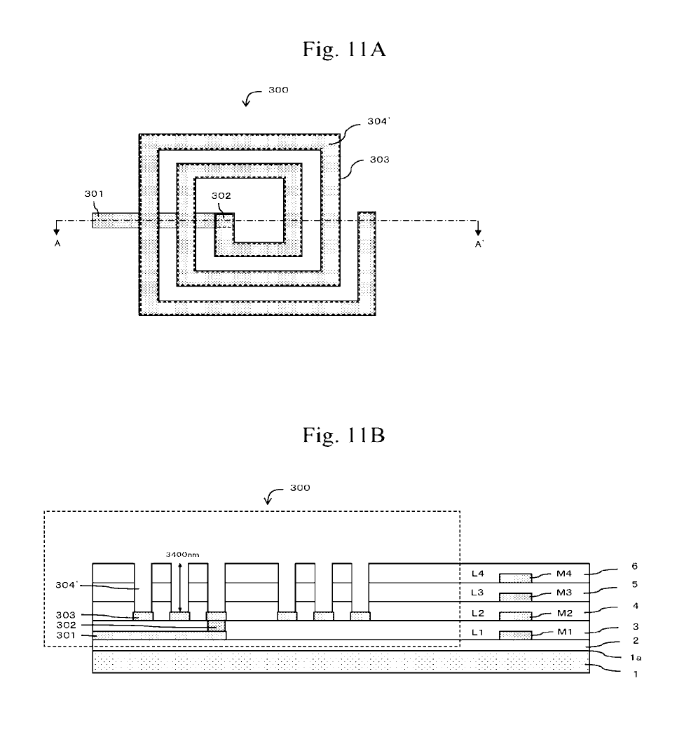

Next, as shown in FIG. 11B, a contact 304′ which exposes the surface of the first conductive pattern 303 is formed with photolithoetching. As shown in FIG. 11A, the contact hole 304′ is illustrated with a dotted line. The contact hole 304′ is formed along the spiral shaped first conductive pattern 303 in a slit shape or a narrow slit shape. More specifically, the contact hole 304′ is formed to be approximately aligned with the first conductive pattern 303 when seen in the top view.

Next, as shown in FIG. 12B, pure aluminum is implanted into the interior of the contact hole 304′ with a selective aluminum chemical vapor deposition method (selective Al CVD method), and thus a contact 304 is formed astride the second to fourth wiring layer L2 to L4. For example, pure aluminum is formed by using a liquid organic metal material, dimethyl aluminum hydride ((CH₃)₂AlH) with the selective Al CVD method. Here, the chamber pressure is set to 1.5 Torr, and the deposition temperature is set to 300-400 degrees Celsius, and the gas flow rate of carrier gas (H₂) is set to 40 sccm. As shown in FIG. 11B, the vertical length (i.e., depth) of the contact 304′ is set to 3400 nm as an example. Here, if the deposition rate of a film is set to 800 nm/min, it will be possible to implant pure aluminum into the inside of the contact 304′ in 4.25 minutes. The selective Al CVD method is the most suitable method for implanting material into a contact hole whose aspect ratio is high, such as the contact hole 304′ in the third embodiment of the present invention, in other words, the contact hole whose vertical length (i.e., depth) is longer than the diameter of the contact hole's opening. In addition, it is possible to use other material such as triisobutil aluminum (TIBA: [(CH₃)₂CHCH₂]₃Al) instead of using dimethyl aluminum hydride ((CH₃)₂AlH) as the material to deposit pure aluminum.

Next, a conductive film (e.g., Al alloy) of 800 nm in thickness is deposited on the interlayer insulation film 6 with the sputtering method, so that the contact hole 304 can be covered with the conductive film. A second conductive pattern 305 and a lead wiring 306, both of which form a portion of the spiral inductor 300, and a fifth wiring M5 which is a normal circuit wiring are formed by patterning the conductive film with photolithoetching. Next, an insulation film (e.g., a silicon dioxide film) of 2000 nm in thickness is deposited on the fifth wiring M5, the second conductive pattern 305, the lead wiring 306, and the interlayer insulating film 6 with the CVD method. Then the insulation film is planarized with the CMP method and thus an interlayer insulation film 7 is formed. The thickness of the interlayer insulation film 7 is set to 1400 nm, for instance. The thickness of the portions of the interlayer insulation film 7 formed on the second conductive pattern 305, the lead wiring 306, and the fifth wiring M5 is set to 600 nm. Thus, a semiconductor device having the spiral inductor 300 is formed.

Here, as an example, thickness “d” of the spiral inductor 300 can be calculated as follows. As shown in FIG. 12B, thickness d is calculated by adding thicknesses of the second wiring layer L2, the third wiring layer L3, the fourth wiring layer L4, and the fifth wiring layer L5 (i.e., d=1400 nm×3+800 nm=5000 nm). Therefore, it is easy to form a spiral inductor of 5 or more μm in thickness.

According to the method for manufacturing a semiconductor device in accordance with the third embodiment of the present invention, the normal circuit wirings (i.e., the first to fifth wirings M1 to M5) and the conductive patterns (i.e., the first and second conductive patterns 301 and 305) are simultaneously formed, and the spiral inductor is formed by connecting both conductive patterns through the slit contact (or the narrow slit contact) 304. Thus, constraints in the width of the wiring and the distance between the wirings, which are caused during the formation of the spiral inductor by using a single layered thick wiring, are alleviated. Because of this, it is possible to reduce the space occupied by the spiral inductor, and thus it is possible to miniaturize a semiconductor device. In addition, the spiral inductor is formed by using a step of forming a normal circuit wiring. Therefore, it is possible to rationalize the manufacturing process and thus it is possible to reduce the manufacturing cost. Furthermore, it becomes possible to easily form a spiral inductor in which a thick film structure is formed astride three layers. Because of this, it is possible to further reduce the resistance of the spiral inductor, and thus it is possible to enhance the spiral inductor's performance. In addition, according to the third embodiment of the present invention, the slit contact (or the narrow slit contact) 304′ is formed astride a plurality of interlayer insulation films (i.e., the interlayer insulation films 4, 5, and 6), and the contact 304 is formed by implanting Al alloy into the contact hole 304′. Therefore, it is possible to omit the step of forming a conductive pattern in each of the third and fourth wiring layers L3 and L4. In other words, it is possible to simply form the mask pattern. Furthermore, according to the third embodiment of the present invention, the slit contact (or the narrow slit contact) 304 is formed by using pure aluminum with the selective Al CVD method. Therefore, it is possible to further reduce resistance of the spiral inductor and thus it is possible to enhance the spiral inductor's performance, compared to the case in which Al alloy is used with a normal sputtering method.

In addition, according to the third embodiment of the present invention, the conductive pattern 303 and the contact 302 are simultaneously formed. Therefore, it is possible to simplify the manufacturing process of the conductive pattern and the contact.

Furthermore, according to the third embodiment present invention, as shown in FIGS. 9A, 9B, 10A, 10B, 11A, 11B, 12A, and 12B, the contact hole 302′ is formed in an end portion of the lead wiring 301. Because of this, it is possible to form the lead wiring 301 in the minimum length. In addition, a plurality of contact holes 302′ may be formed in an end portion of the lead wiring 301. On the other hand, the contact hole 304′ is formed in an edge portion of the lead wiring 306. Because of this, it is possible to form the lead wiring 306 in the minimum length. In addition, a plurality of contact holes 304′ may be formed in an edge of the lead wiring 306.

In addition, the lead wirings 301 and 306, the first and second conductive patterns 303 and 305, and the contact 304 may be formed with aluminum alloy (i.e., an alloy mainly comprised of aluminum). In this case, it is possible to form the spiral inductor by using a heretofore known method for forming a wiring layer.

This application claims priority to Japanese Patent Application No. 2005-119387. The entire disclosure of Japanese Patent Application No. 2005-119387 is hereby incorporated herein by reference.

The terms of degree such as “approximately” used herein mean a reasonable amount of deviation of the modified term such that the end result is not significantly changed. For example, the terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims.

Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A method for manufacturing a semiconductor device in which a plurality of wiring layers are formed, comprising the steps of:
preparing a semiconductor device on which a plurality of semiconductor elements are formed on one surface thereof;
forming a spiral inductor on the semiconductor substrate astride three or more wiring layers; and
forming a circuit wiring other than the spiral inductor in the plurality of wiring layers;
wherein the step of forming the spiral inductor and the step of forming the circuit wiring are performed simultaneously.

2. The method according to claim 1, wherein the step of forming the spiral inductor further comprises the steps of:
forming a first lead wiring in a first wiring layer;
forming an interlayer insulation film in the first wiring layer, the first interlayer insulation film covering the first lead wiring;
forming a first contact hole in the first interlayer insulation film, the first contact hole exposing a portion of the surface of the first lead wiring;
forming a first contact by implanting a conductive material into the interior of the first contact hole;
forming a spiral shaped first conductive pattern in a second wiring layer located on the first wiring layer, the spiral shaped first conductive pattern connected to the first lead wiring through the first contact;
forming a second interlayer insulation film in the second wiring layer, the second interlayer insulation film covering the first conductive pattern;
forming a second contact hole in the second interlayer insulation film, the second contact hole exposing a portion of the surface of the first conductive pattern;
forming a second contact by implanting a conductive material into the interior of the second contact hole;
forming a spiral shaped second conductive pattern in a third wiring layer located on the second wiring layer, the spiral shaped second conductive pattern connected to the first conductive pattern through the second contact and overlapped with the first conductive pattern; and
forming a second lead wiring that is connected to an end portion of the second conductive pattern and integrated with the second conductive pattern.

3. The method according to claim 2, wherein a plurality of second contact holes are formed on the first conductive pattern at predetermined intervals.

4. The method according to claim 2, wherein the step of forming the second contact and the step of forming the second conductive pattern are performed simultaneously.

5. The method according to claim 2, wherein one or more first contact holes are formed in an end portion of the first lead wiring.

6. The method according to claim 2, wherein the step of forming the first contact and the step of forming the first conductive pattern are performed simultaneously.

7. The method according to claim 2, wherein the second contact hole is formed in a slit planar shape and formed along the first conductive pattern.

8. The method according to claim 1, wherein the step of forming the spiral inductor further comprises the steps of:
forming a first lead wiring in a first wiring layer;
forming an interlayer insulation film in the first wiring layer, the first interlayer insulation film covering the first lead wiring;
forming a first contact hole in the first interlayer insulation film, the first contact hole exposing a portion of the surface of the first lead wiring;
forming a first contact by implanting a conductive material into the interior of the first contact hole;
forming a spiral shaped first conductive pattern in a second wiring layer located on the first wiring layer, the spiral shaped first conductive pattern connected to the first lead wiring through the first contact;
forming a second interlayer insulation film in the second wiring layer, the second interlayer insulation film covering the first conductive pattern;
forming a second contact hole in the second interlayer insulation film, the second contact hole exposing a portion of the surface of the first conductive pattern;
forming a second contact by implanting a conductive material into the interior of the second contact hole;
forming a spiral shaped second conductive pattern in a third wiring layer located on the second wiring layer, the spiral shaped second conductive pattern connected to the first conductive pattern through the second contact and overlapped with the first conductive pattern;
forming a third interlayer insulation film in the third wiring layer, the third insulation film covering the second conductive pattern;
forming a third contact hole in the third interlayer insulation film, the third contact hole exposing a portion of the surface of the second conductive pattern;
forming a third contact by implanting a conductive material into the interior of the third contact;
forming a spiral shaped third conductive pattern in a fourth wiring layer located on the third wiring layer, the spiral shaped third conductive pattern connected to the second conductive pattern through the third contact and overlapped with the second conductive pattern;
forming a fourth interlayer insulation film in the fourth wiring layer, the fourth interlayer insulation film covering the third conductive pattern;
forming a fourth contact hole in the fourth interlayer insulation film, the fourth contact hole exposing a portion of the surface of the third conductive pattern;
forming a fourth contact by implanting a conductive material into the interior of the fourth contact hole;
forming a spiral shaped fourth conductive pattern in a fifth wiring layer located on the fourth wiring layer, the spiral shaped fourth conductive pattern connected to the third conductive pattern through the fourth contact and overlapped with the third conductive pattern; and
forming a second wiring that is connected to an end portion of the fourth conductive pattern and integrated with the fourth conductive pattern.

9. The method according to claim 8, wherein
a plurality of the second contact holes are formed on the first conductive pattern at predetermined intervals;
a plurality of the third contact holes are formed on the second conductive pattern at predetermined intervals; and
a plurality of the fourth contact holes are formed on the third conductive pattern at predetermined intervals.

10. The method according to claim 8, wherein
the step of forming the second contact and the step of forming the second conductive pattern are performed simultaneously;
the step of forming the third contact and the step of forming the third conductive pattern are performed simultaneously; and
the step of forming the fourth contact and the step of forming the fourth conductive pattern are performed simultaneously;

11. The method according to claim 8, wherein one or more first contacts are formed in an edge portion of the first lead wiring.

12. The method according to claim 8, wherein the step of forming the first contact and the step of forming the first conductive pattern are performed simultaneously.

13. The method according to claim 8, wherein the first lead wiring, the second lead wiring, the first conductive pattern, the second conductive pattern, the third conductive pattern, the fourth conductive pattern, the first contact, the second contact, the third contact, and the fourth contact are comprised of am alloy that is primarily comprised of aluminum.

14. The method according to claim 8, wherein
the second contact hole is formed in a slit planar shape and formed along the first conductive pattern;
the third contact hole is formed in a slit planar shape and formed along the second conductive pattern; and
the fourth contact hole is formed in a slit planar shape and formed along the third conductive pattern.

15. The method according to claim 1, wherein the step of forming the spiral inductor is comprised of the steps of:
forming a first lead wiring in a first wiring layer;
forming an interlayer insulation film in the first wiring layer, the first interlayer insulation film covering the first lead wiring;
forming a first contact hole in the first interlayer insulation film, the first contact hole exposing a portion of the surface of the first lead wiring;
forming a first contact by implanting a conductive material into the interior of the first contact hole;
forming a spiral shaped first conductive pattern in a second wiring layer located on the first wiring layer, the spiral shaped first conductive pattern connected to the first lead wiring through the first contact;
forming a second interlayer insulation film in the second wiring layer, the second interlayer insulation film covering the first conductive pattern;
forming a third interlayer insulation film in a third wiring layer located on the second wiring layer;
forming a fourth interlayer insulation film in a fourth wiring layer located on the third wiring layer;
integrally forming a second contact hole in the second interlayer insulation film, the third interlayer insulation film, and the fourth interlayer insulation film, the second contact hole exposing a portion of the surface of the first conductive pattern;
forming a second contact by implanting a conductive material into the interior of the second contact hole;
forming a spiral shaped second conductive pattern in a fifth wiring layer located on the fourth wiring layer, the spiral shaped second conductive pattern connected to the first conductive pattern through the second contact and overlapped with the first conductive pattern; and
forming a second lead wiring that is connected to an end portion of the second conductive pattern and integrated with the second conductive pattern.

16. The method according to claim 15, wherein the second contact hole is formed in a slit planar shape and formed along the first conductive pattern.

17. The method according to claim 15, wherein the step of forming the second contact is conducted with a selective aluminum chemical vapor deposition method and not simultaneously conducted with the step of forming the second conductive pattern.

18. The method according to claim 15, wherein one or more first contacts are formed in an edge portion of the first lead wiring.

19. The method according to claim 15, wherein the step of forming the first contact and the step of the first conductive pattern are performed simultaneously.

20. The method according to claim 15, wherein the first lead wiring, the second lead wiring, the first conductive pattern, the second conductive pattern, and the first contact are comprised of an alloy that is primarily comprised of aluminum.
